(19) United States
(12) Patent Application Publication
(10) Pub. No.: US 2026/0227634 A1
(43) Pub. Date: Aug. 6, 2026

(54) ELECTRONIC DEVICE

(71) Applicant: LG ELECTRONICS INC., Seoul (KR)

(72) Inventors: Eujin KIM, Seoul (KR); Wonseok JOO, Seoul (KR); Jungyun LEE, Seoul (KR); Dongchul JIN, Seoul (KR); Hoyoun LEE, Seoul (KR); Youngwook KIM, Seoul (KR)

(73) Assignee: LG ELECTRONICS INC., Seoul (KR)

(21) Appl. No.: 19/152,901

(22) PCT Filed: Feb. 2, 2023
(86) PCT No.: PCT/KR2023/001517

§ 371 Date: Jul. 31, 2025

(51) Int. Cl. G02B 27/01; G02C 5/14; G02C 11/00

(52) U.S. Cl. CPC G02B 27/0176; G02C 5/14; G02C 11/10; G02B 2027/0178

(57) ABSTRACT

The present disclosure relates to an electronic device. The electronic device includes: a front frame to which a light-transmissive display unit is coupled; and a temple which is elongated and connected to the front frame, wherein the front frame includes: a PCB embedded in the front frame and extending from the front frame toward the temple; and a display panel embedded in the front frame at one side of the display unit and electrically connected to the PCB, wherein the temple includes: a flat board embedded in the temple and electrically connected to the PCB of the front frame; an input board embedded in the temple and electrically connected to the flat board; and a vibration sensor mounted on the input board, wherein the vibration sensor is fixed to an inside of the temple.

### TECHNICAL FIELD

The present disclosure relates to an electronic device, and more particularly to an electronic device used for Virtual Reality (VR), Augmented Reality (AR), Mixed Reality (MR), etc.

### BACKGROUND ART

Virtual reality (VR) refers to any specific environment or situation that is similar to reality but created by artificial technology using computers, or the technology itself.

Augmented reality (AR) refers to technology that synthesizes a virtual object or information with a real environment so that it looks like an object existing in the original environment.

Mixed reality (MR) or hybrid reality refers to creation of a new environment or new information by combining a virtual world with a real world. In particular, it is called mixed reality when it is possible to interact in real time between what exists in real and virtual in real time.

Created virtual environment or situation stimulates the five senses of the users and allows them to experience spatial and temporal experiences that are similar to reality to freely cross the boundary between reality and imagination. In addition, users may not only be immersed in these environments, but also interact with things that are implemented in these environments, such as by manipulating or instructing them using real devices.

Recently, research has been actively conducted on the gear used in this technical field.

### DISCLOSURE OF INVENTION

### Technical Problem

It is an objective of the present disclosure to solve the above and other problems.

It is another objective of the present disclosure to provide an electronic device used for Virtual Reality (VR), Augmented Reality (AR), Mixed Reality (MR), and the like.

It is yet another objective of the present disclosure to provide a structure of an electronic device used for Augmented Reality (AR).

It is yet another objective of the present disclosure to provide an ergonomic structure of an electronic device used for Augmented Reality (AR).

It is yet another objective of the present disclosure to provide a user interface structure of an electronic device used for Augmented Reality (AR).

It is yet another objective of the present disclosure to provide a touch control system of an electronic device used for Augmented Reality (AR).

### Solution to Problem

In accordance with an aspect of the present disclosure, the above and other objectives can be accomplished by providing an electronic device including: a front frame to which a light-transmissive display unit is coupled; and a temple which is elongated and connected to the front frame, wherein the front frame includes: a PCB embedded in the front frame and extending from the front frame toward the temple; and a display panel embedded in the front frame at one side of the display unit and electrically connected to the PCB, wherein the temple includes: a flat board embedded in the temple and electrically connected to the PCB of the front frame; an input board embedded in the temple and electrically connected to the flat board; and a vibration sensor mounted on the input board, wherein the vibration sensor is fixed to an inside of the temple.

### Advantageous Effects of Disclosure

The electronic device according to the present disclosure has the following effects.

According to at least one of the embodiments of the present disclosure, an electronic device used for Virtual Reality (VR), Augmented Reality (AR), Mixed Reality (MR), and the like may be provided.

According to at least one of the embodiments of the present disclosure, a structure of an electronic device used for Augmented Reality (AR) may be provided.

According to at least one of the embodiments of the present disclosure, an ergonomic structure of an electronic device used for Augmented Reality (AR) may be provided.

According to at least one of the embodiments of the present disclosure, a user interface structure of an electronic device used for Augmented Reality (AR) may be provided.

According to at least one of the embodiments of the present disclosure, a touch control system used for Augmented Reality (AR) may be provided.

Further scope of applicability of the present disclosure will become apparent from the detailed description given hereinafter. However, it should be understood that the detailed description and specific examples, while indicating preferred embodiments of the present disclosure, are given by illustration only, since various changes and modifications within the spirit and scope of the present disclosure will become apparent to those skilled in the art from this detailed description.

### BRIEF DESCRIPTION OF DRAWINGS

FIGS. 1 to 23 are diagrams illustrating examples of an electronic device according to embodiments of the present disclosure.

### MODE OF DISCLOSURE

Hereinafter, the present disclosure will be described in detail with reference to the accompanying drawings, in which the same reference numerals are used throughout the drawings to designate the same or similar components, and a redundant description thereof will be omitted.

The suffixes, such as “module” and “unit,” for elements used in the following description are given simply in view of the ease of the description, and suffixes do not have any special meaning or function.

In addition, it will be noted that a detailed description of known arts will be omitted if it is determined that the detailed description of the known arts can obscure the embodiments of the present disclosure. Further, the accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A singular representation may include a plural representation unless context clearly indicates otherwise.

In the present application, it should be understood that the terms “comprises,” “includes,” “has,” etc. specify the presence of features, numbers, steps, operations, elements, components, or combinations thereof described in the specification, but do not preclude the presence or addition of one or more other features, numbers, steps, operations, elements, components, or combinations thereof.

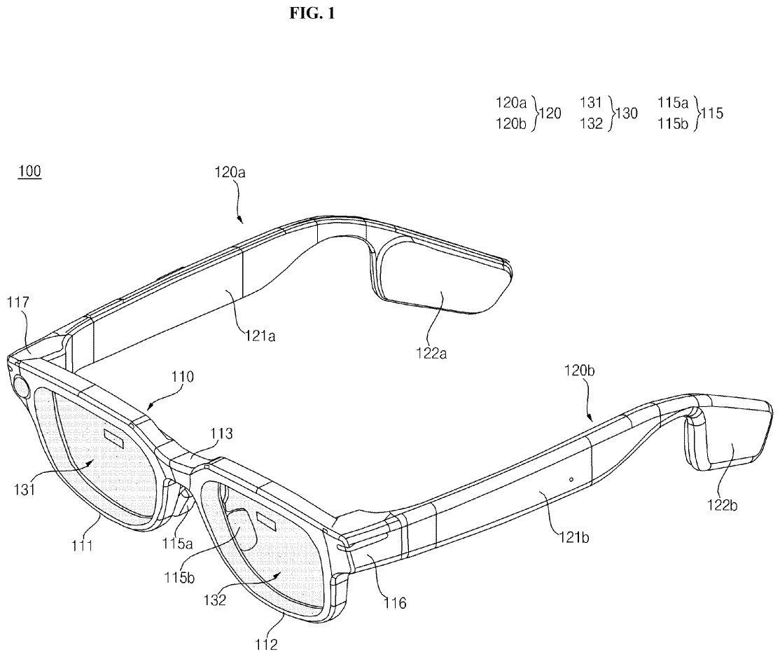

Referring to FIG. 1, an electronic device 100 may be generally in the form of glasses or goggles. The electronic device 100 may include a frame 110 and 120 and a display unit 130.

The frame 110 and 120 may include a front frame 110, a side frame 120, and a nose support 115. The front frame 110 may include a plurality of rims 111 and 112, a bridge 113, and an end piece 116 and 117. The bridge 113 may connect a first rim 111 and a second rim 112. A shape of an opening of the rim 111 and 112 may correspond to a shape of the display unit 130. For example, the display unit 130 may be coupled or fixed to the opening of the rim 111 and 112. A first end piece 117 may be opposite the bridge 113 with respect to the first rim 111, and a second end piece 116 may be opposite the bridge 113 with respect to the second rim 112. The front frame 110 may be laterally symmetrical about the center of the bridge 113.

The side frame 120 may be coupled to the front frame 110. The side frame 120 may be hingedly coupled to the end piece 116 and 117. For example, a first side frame 120a may be hingedly coupled to the first end piece 117, and a second side frame 120b may be hingedly coupled to the second end piece 116. The side frame 120 may include temples 121a and 121b and temple tips 122a and 122b. The temples 121a and 121b may be hingedly coupled to the end pieces 116 and 117. The temple tips 122a and 122b may be opposite the end pieces 116 and 117 with respect to the temples 121a and 121b.

The nose support 115 may be coupled to the bridge 113 or the rims 111 and 112. For example, a first nose support 115a may be coupled to the first rim 111 or the bridge 113, and a second nose support 115b may be coupled to the second rim 112 or the bridge 113. Depending on the structure of the frame 110 and 120, the nose support 115 may be omitted or may be formed as one body with the front frame 110.

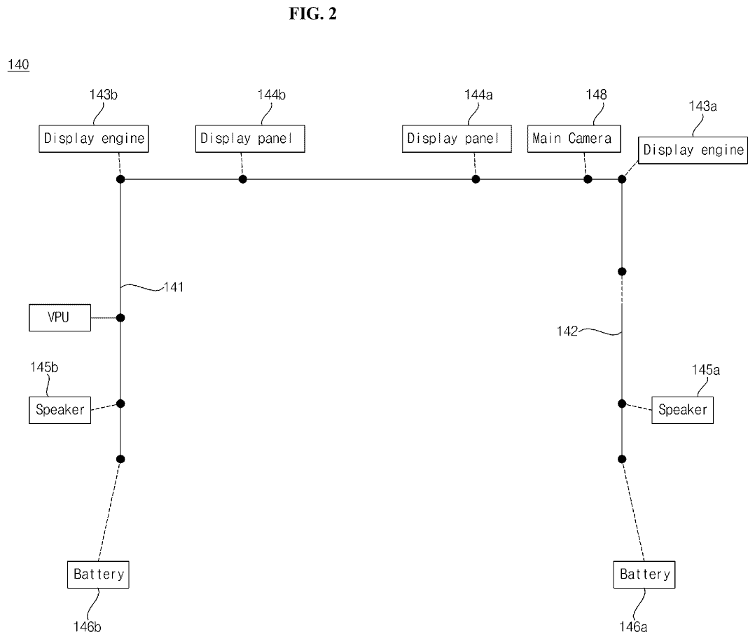

Referring to FIG. 2, the electronic device 100 (see FIG. 1) may include a main PCB 142 and a sub PCB 141. For example, the main PCB 142 and/or the sub PCB 141 may be flexible printed circuit boards (F-PCB). The sub PCB 141 may be elongated and may be embedded in the frame 110 and 120. For example, the sub PCB 141 may be embedded in the front frame 110, the second end piece 116, and/or the second side frame 120b. In another example, the sub PCB 141 may be embedded in the front frame 110, the first end piece 117, the second end piece 116, the first side frame 120a, and/or the second side frame 120b.

The main PCB 142 may be embedded in the frame 110 and 120 and may be electrically connected to the sub PCB 141. For example, the main PCB 142 may be embedded in the first side frame 120a and may be connected to the sub PCB 141.

A first battery 146a may be electrically connected to the main PCB 142 and may supply power to the main PCB 142. A second battery 146b may be electrically connected to the sub PCB 141 and may supply power to the sub PCB 141. A first speaker 145a may be electrically connected to the main PCB 142 and may output sound by receiving a signal from the main PCB 142. A second speaker 145b may be electrically connected to the sub PCB 141 and may output sound by receiving a signal from the sub PCB 141.

A first display engine 143a and/or a second display engine 143b may be electrically connected to the sub PCB 141. A first display panel 144a and/or a second display panel 144b may be electrically connected to the sub PCB 141. The first display engine 143a may provide an image signal, a video signal, or a text signal to the first display panel 144a, and the second display engine 143b may provide an image signal, a video signal, or a text signal to the second display panel 144b. For example, the display panel 144a and 144b may be a micro LED, OLED, and OLEDos (OLED on silicon). The display engine 143 and the display panel 144 may be referred to as imaging modules 143 and 144, imaging engines 143 and 144, image generators 143 and 144, or display modules 143 and 144.

Referring together to FIG. 1, the first display engine 143a may be embedded in the first end piece 117, and the first display panel 144a may be embedded in the first rim 111. The second display engine 143b may be embedded in the second end piece 116, and the second display panel 144b may be embedded in the second rim 112. A main camera 148 may be electrically connected to the sub PCB 141 and may be embedded in the first end piece 117.

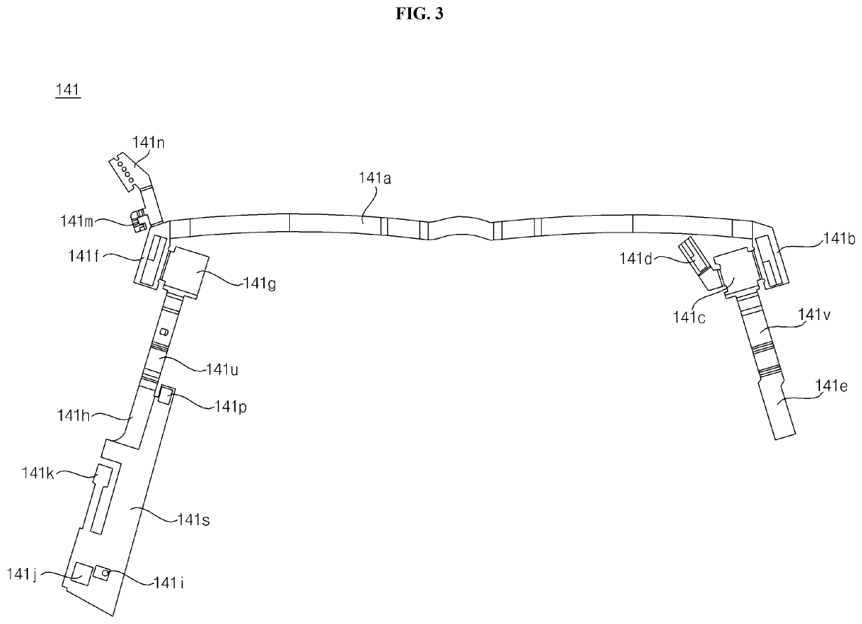

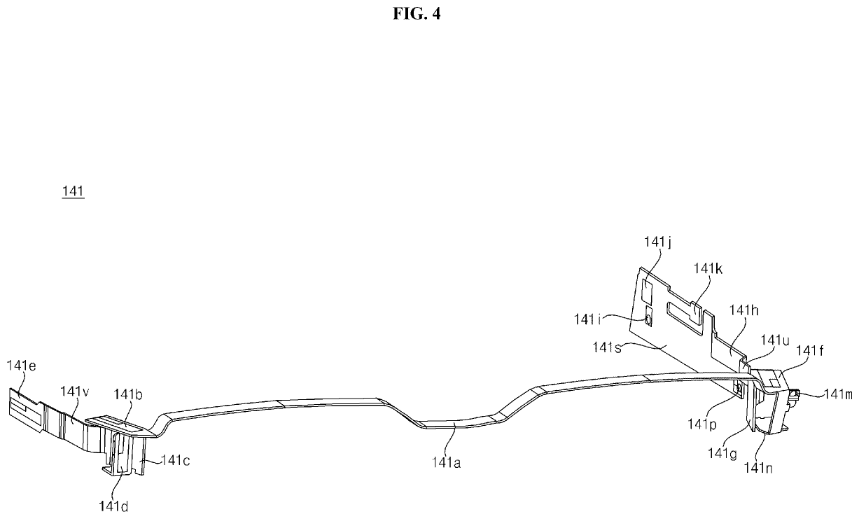

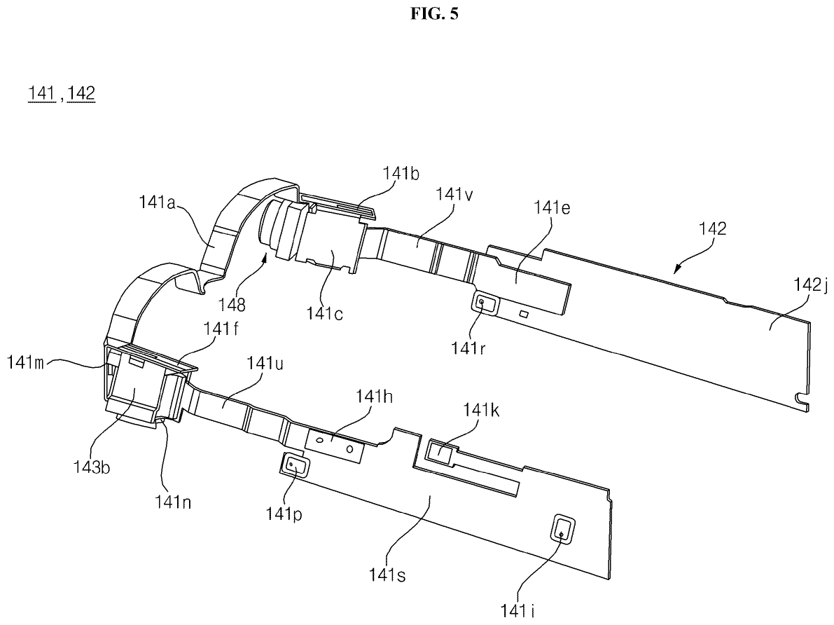

Referring to FIGS. 3 to 5 together with FIG. 2, the sub PCB 141 may include a main line 141a, a first display connector 141b, a camera module connector 141d, a first display board 141c, a main board connector 141e, a second display connector 141f, a second display board 141g, a sensor connector 141m, an electrode board 141n, a switching board 141h, a first microphone board 141i, a second power connector 141j, a second microphone board 141k, a third microphone board 141p, and/or a fourth microphone board 141r. The microphone boards 141i, 141k, and 141p may be referred to as input boards 141i, 141k, and 141p. An electronic component for user input may be mounted on the input boards 141i, 141k, and 141p. For example, the electronic component may be a Micro Electro Mechanical System (MEMS).

The main line 141amay be elongated and may have a smaller width than widths of the rims 111 and 112 of the front frame 110 (see FIG. 1). The first display connector 141b may be formed at a first end of the main line 141a. The first display panel 144a may be connected to the first display connector 141b. The first display board 141c may bend and extend from the first display connector 141b. The first display engine 143a including electronic components for image generation may be mounted on the first display board 141c. For example, an image processor, a T-CON board, and the like may be mounted on the first display board 141c.

The camera module connector 141d may bend and extend from the first display board 141c. The main camera 148 may be connected to the camera module connector 141d. The main board connector 141e may extend from the first display board 141c. The main board 142 may be connected to the main board connector 141e.

The second display connector 141f may be formed at a second end of the main line 141a. The second display panel 144b may be connected to the second display connector 141f. The second display board 141g may bend and extend from the second display connector 141f. The second display engine 143b including electronic components for image generation may be mounted on the second display board 141g. For example, an image processor, a T-CON board, and the like may be mounted on the second display board 141g.

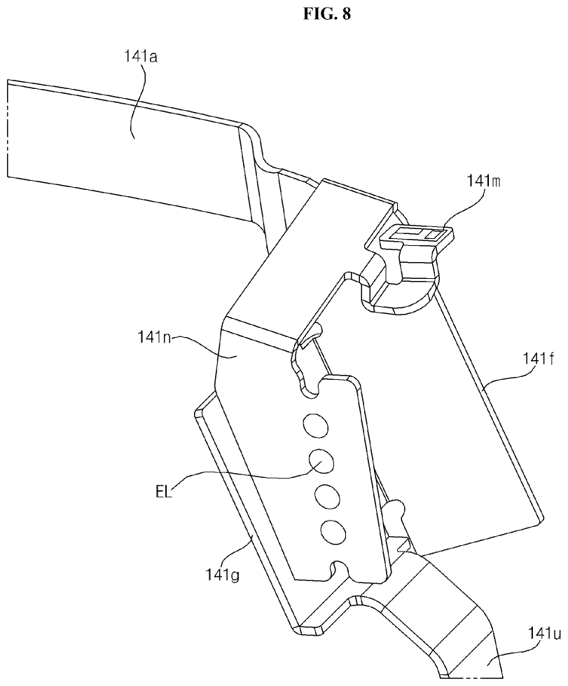

The electrode board 141n may be connected to the main line 141aor the second display connector 141f. The electrode board 141n may be electrically connected to an external device by contact with a device provided from the outside. For example, the electrode board 141n may include a plurality of terminals EL (see FIG. 8).

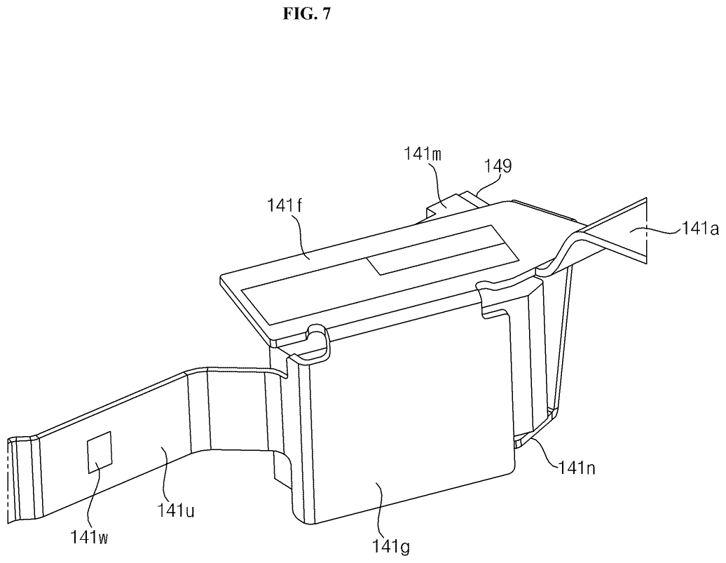

The sensor connector 141m may be connected to the main line 141a or the electrode board 141n. Sensors 149 (see FIG. 7) configured to detect an external environment may be connected to the sensor connector 141m. For example, the sensor 149 may be an illumination sensor.

A flat board 141s may be connected to the second display board 141g. The second microphone board 141k may extend from one side of the flat board 141s. The first microphone board 141i may be formed on the flat board 141s. The second power connector 141j may be formed on the flat board 141s. The flat board 141s may be connected to the second display board 141g by a second hinge FPCB 141u. The switching board 141h may be adjacent to the second hinge FPCB 141u and formed on the flat board 141s. The third microphone board 141p may be adjacent to the switching board 141h and formed on the flat board 141s.

The main board connector 141e may be connected to the first display board 141c by a first hinge FPCB 141v. The fourth microphone board 141r may be adjacent to the main board connector 141e and formed on the main PCB 142. A first power connector 142j may be formed on the main PCB 142.

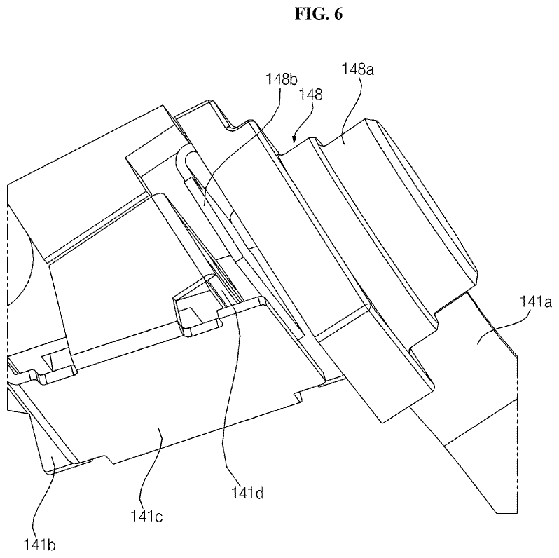

Referring to FIGS. 6 and 7, the main camera 148 may be coupled to the camera module connector 141d. The main camera 148 may include a camera module 148a and a connection terminal 148b. The camera module 148a may include an imaging device to convert light coming from an external source into an electrical signal. The connection terminal 148b may be connected to the camera module 148a. The connection terminal 148b may be electrically connected to the imaging device. The connection terminal 148b may be fixed to the camera module connector 141d. The connection terminal 148b may be electrically connected to the camera module connector 141d.

The sensor 149 may be mounted on the sensor connector 141m. The sensor 149 may be electrically connected to the sensor connector 141m. For example, the sensor 149 may be an illumination sensor 149.

The second display engine 143b including electronic components for image generation may be mounted on the second display board 141g. For example, an image processor, a T-CON board, and the like may be mounted on the second display board 141g.

A hall sensor 141w may be formed or mounted on the second hinge board 141u.

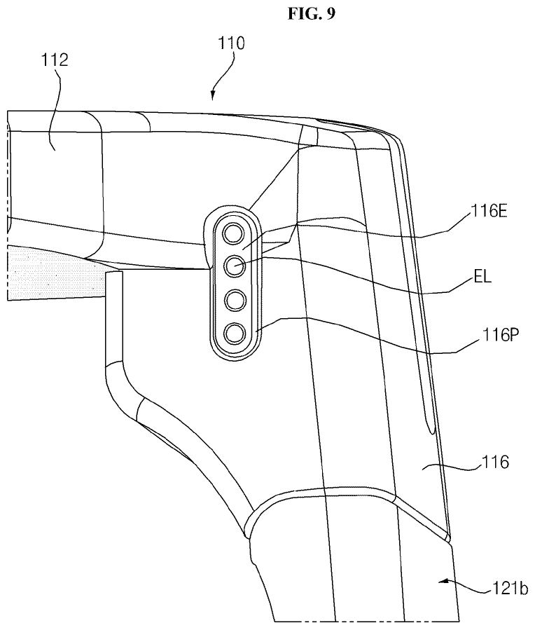

Referring to FIGS. 8 and 9, a plurality of terminals EL may be fixed to the electrode board 141n. The plurality of terminals EL may be arranged in a line. The plurality of terminals EL and the electrode board 141n may be positioned inside the second end piece 116. A terminal opening 116p may be formed in the second end piece 116. The terminal opening 116p may be elongated. A terminal cover 116E may have a shape corresponding to the terminal opening 116p and may be inserted into the terminal opening 116p. The terminal cover 116E may have a plurality of holes. Each of the plurality of holes may correspond to each of the plurality of terminals EL. The terminals EL may be exposed to the outside through the plurality of holes of the terminal cover 116E. The terminals EL may be used for charging the electronic device 100.

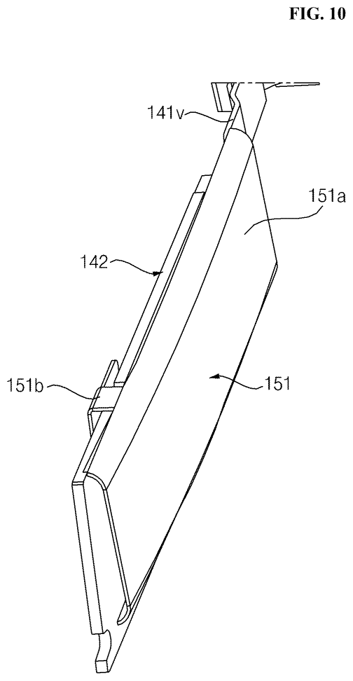

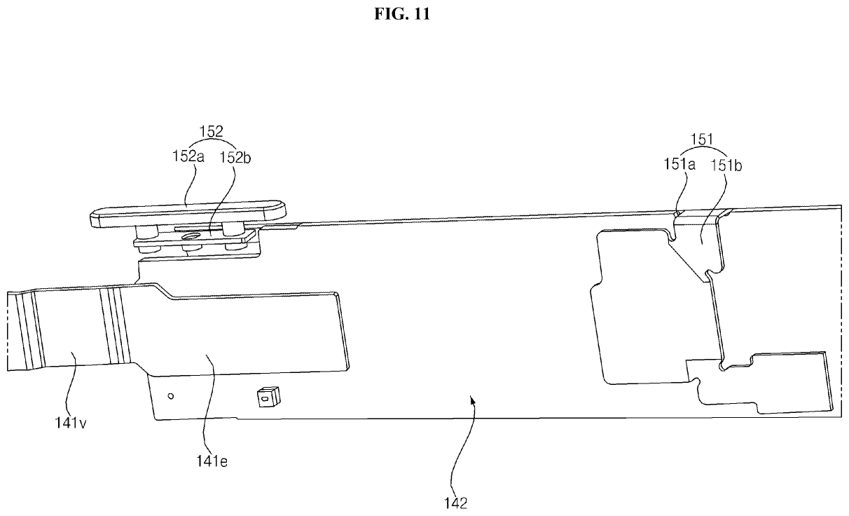

Referring to FIGS. 10 and 11, a touch pad 151 may be connected to the main PCB 142. The touch pad 151a may include a touch panel 151a and a panel electrode 151b. The touch panel 151a may be located on an outer surface of the main PCB 142 and may face the outer surface of the main PCB 142. For example, the touch panel 151a may be a capacitive sensing panel. In another example, the touch panel 151a may be a static pressure sensing panel. A panel electrode 151b may electrically connect the main PCB 142 and the touch panel 151a.

A camera switch 152 may be mounted on the main PCB 142. The camera switch 152 may be located on an upper side of the main PCB 142 and electrically connected to the main PCB 142. The camera switch 152 may control the operation of the main camera 148. The camera switch 152 may include a button 152a and a switching unit 152b. An electrical signal may be generated by contact with the switching unit 152b when the button 152a is pressed. For example, the camera switch 152 may function as a shutter button for the camera.

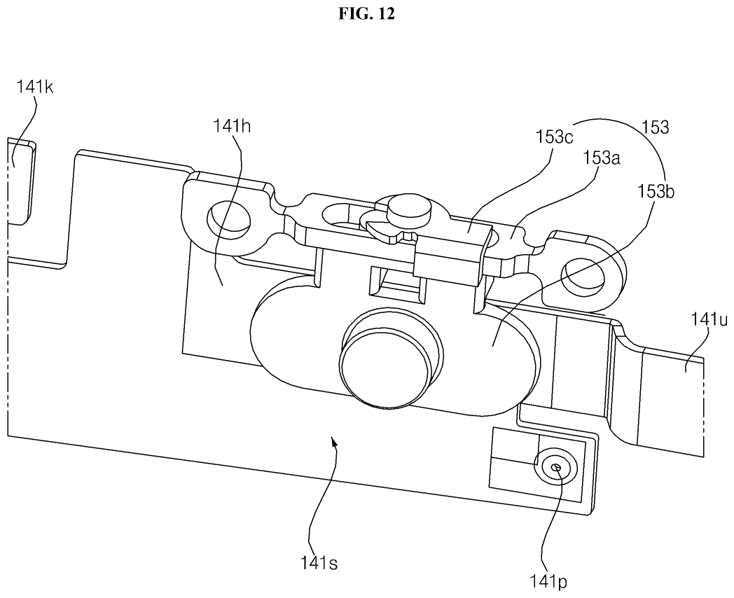

Referring to FIG. 12, a power switch 153 may include a base 153a, a switching button 153b, and a connector 153c. The base 153a may be located on an upper side of the flat board 141s. The switching button 153b may move by sliding on the base 153a. The connector 153c may connect the switching button 153b and the base 153a. The switching button 153b may electrically contact the switching board 141h of the flat board 141s. An electrical signal generated by the switching button 153b and the switching board 141h of the flat board 141s may vary depending on the position of the switching button 153b. For example, the switching button 153b may move on the base 153a from the second microphone board 141k to the second hinge FPCB 141u. When the switching button 153b moves on the base 153a to a position that is closest possible to the second hinge FPCB 141u, the electronic device 100 may be turned ON. The switching button 153b may return to its original position from the base 153a. In order to allow the switching button 153b to return to its original position, elastic force may be provided to the switching button 153b.

For example, when a user maximally presses the switching button 153b in an intermediate position toward the second hinge FPCB 141u, the electronic device 100 may be activated, and the switching button 153 may return to the intermediate position. If the user does not use the electronic device 100 for a predetermined period of time, the electronic device 100 may enter a power saving mode. In order to use the electronic device 100 again, the user may press the switching button 153b toward the second hinger FPCB 141u to activate the electronic device 100. When the switching button 153b is pressed toward the second microphone board 141k, the electronic device 100 is deactivated and enters an OFF mode.

In another example, when a user maximally presses the switching button 153b in the intermediate position toward the second hinge FPCB 141u in order to use the electronic device 100, the electronic device 100 may be activated, and the switching button 153 may return to the intermediate position. In order to connect the electronic device 100 with another device, the user may press the switching button 153b toward the second hinge FPCB 141u to activate wireless connectivity. For example, wireless connection may include Bluetooth, Wi-Fi, NFC, and the like. The power switch 153 may be referred to as a function switch 153.

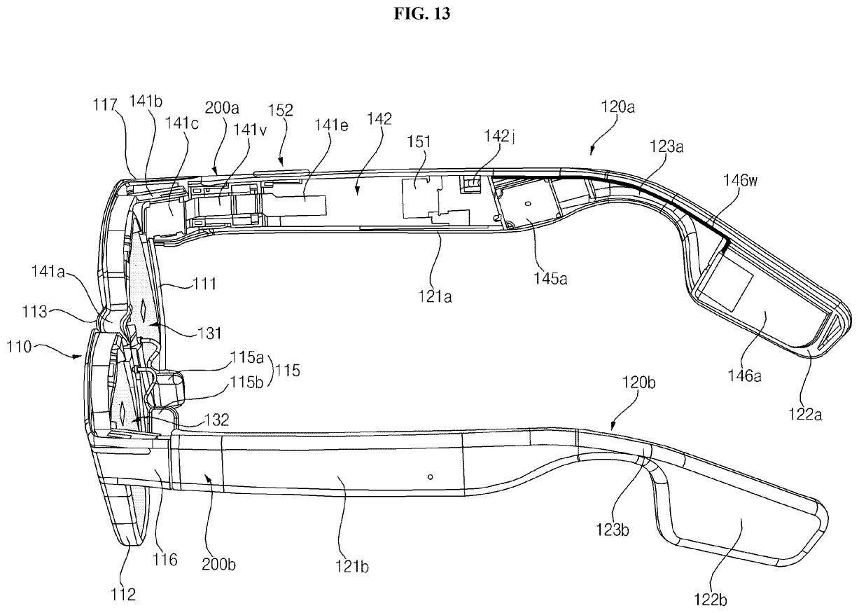

Referring to FIG. 13, the main line 141a may be positioned inside the upper side of the front frame 110. For example, the main line 141a may be embedded in an upper surface of the first rim 111, an upper surface of the bridge 113, and/or an upper surface of the second rim 112. The first display connector 141b, the first display board 141c, and/or the camera module connector 141d may be embedded in the first end piece 117. The main PCB 142 may be embedded in the temple 121a of the first side frame 120a. The first side frame 120a may be hingedly coupled to the first end piece 117. The first hinge FPCB 141v connecting the first display board 141c and the main PCB 142 may be embedded in a first hinge 200a connecting the first end piece 117 and the first side frame 120a and/or the temple 121a of the first side frame 120a. The camera switch 152 may be exposed to the outside through the temple 121a of the first side frame 120a.

The first speaker 145a may be electrically connected to the main PCB 142 and embedded in the temple 121a of the first side frame 120a. The first battery 146a may be embedded in the temple tip 122a of the first side frame 120a. The first battery 146a may be electrically connected to the main PCB 142 through a wire 146w. The first battery 146a may supply power to the main PCB 142.

The side frames 120a and 120b may include ear portions 123a and 123b connecting the temples 121a and 121b and the temple tips 122a and 122b. The wire 146w may connect the first battery 146a and the first power connector 142j of the main PCB 142 inside the temple 121a of the first side frame 120a, inside the ear portion 123a, and inside the temple tip 122a.

The battery 145a may be relatively heavy in weight due to other electronic components. The battery 146a may be embedded in the temple tip 122a, and other electronic components may be embedded in the front frame 110 and the temple 121a. Accordingly, when a user wears the electronic device 100 on the face, the weight of the electronic device 100 is distributed across the user's ears, such that the electronic device 100 may be stably worn on the user.

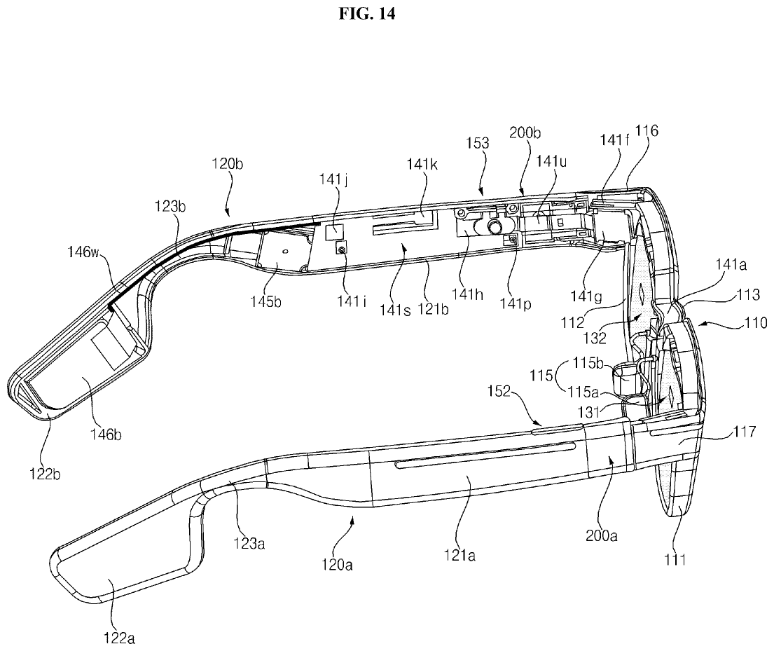

Referring to FIG. 14, the second display connector 141f and the second display board 141g may be embedded in the second end piece 116. The flat board 141s may be embedded in the temple 121b of the second side frame 120b. The temple 121b of the second side frame 120b may be connected to the second end piece 116 via a hinge 200b. The second hinge 200b may allow the second side frame 120b to be hingedly coupled to the second end piece 116.

The second hinge FPCB 141u connecting the second display board 141g and the flat board 141s may be embedded in the second hinge 200b and/or the temple 121b of the second side frame 120b. The power switch 153 may be embedded in the temple 121b of the second side frame 120b, and the switching button 153b (see FIG. 12) may be exposed to the outside through the temple 121b of the second side frame 120b.

The second speaker 145b may be embedded in the temple 121b of the second side frame 120b. The second battery 146b may be embedded in the temple tip 122b of the second side frame 120b. The wire 146w may electrically connect the second battery 146b to the sub PCB 141 (see FIG. 3). For example, the wire 146w may be embedded in the second temple tip 122b, the ear portion 123b, and/or the second temple 121b, and may electrically connect the second battery 146b to the second power connector 141j of the sub PCB 141.

The battery 146b may be relatively heavy in weight due to other electronic components. The battery 146b may be embedded in the temple tip 122b, and other electronic components may be embedded in the front frame 110 and the temple 121b. Accordingly, when a user wears the electronic device 100 on the face, the weight of the electronic device 100 is distributed across the user's ears, such that the electronic device 100 may be stably worn on the user.

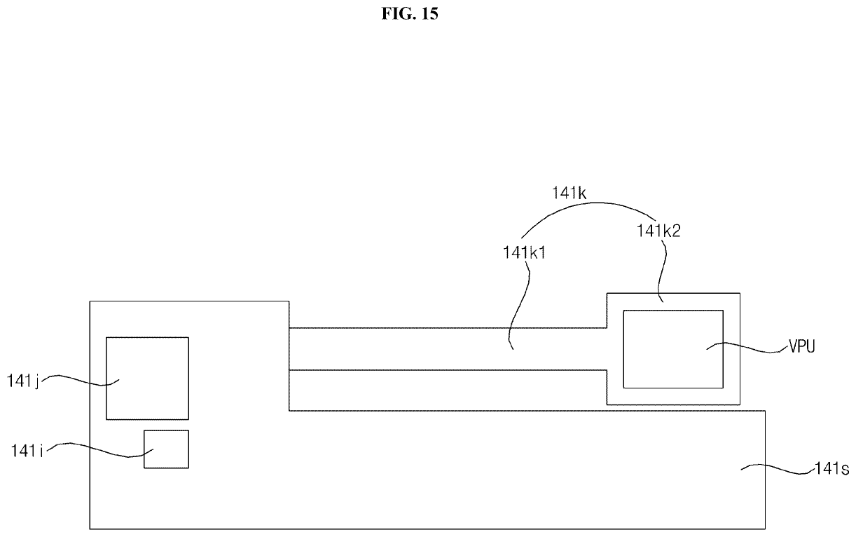

Referring to FIG. 15, the first input board 141i may be formed or mounted on the flat board 141s. For example, the first input board 141i may include a microphone device 141i. The second power connector 141j may be formed or mounted on the flat board 141s.

The second input board 141k may extend from the flat board 141s or may be connected to the flat board 141s. For example, the second input board 141k may be a PCB, and the second input board 141k may extend from the flat board 141s. In another example, the second input board 141k may be an FPCB, and the second input board 141k may be connected to the flat board 141s. The second input board 141k may include a neck 141kl and a head 141k2. The neck 141kl may be electrically connected to the flat board 141s or may extend from the flat board 141s. The head 141k2 may be formed at an end of the neck 141k1.

An input device VPU may be mounted or disposed on the head 141k2 of the second input board 141k. For example, the input device VPU may be MEMS, and may convert external physical vibration into an electrical signal. In another example, the input device VPU may be a vibration process unit (VPU). The input device VPU may detect vibration generated from the outside and generate an electrical signal.

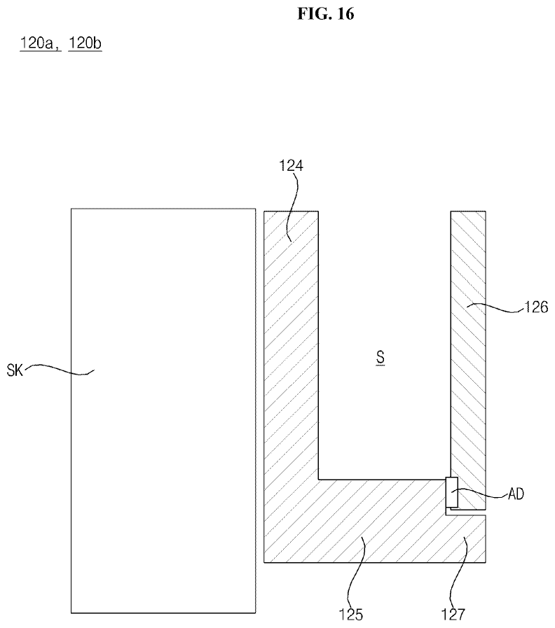

Referring to FIG. 16, the side frame 120a and 120b may include an inner cover 124 and 125 and an outer cover 126. The outer cover 126 may be coupled to the inner cover 124 and 125. The inner cover 124 and 125 may be in contact with body tissue SK forming the appearance of a user. For example, the inner cover 124 and 125 may be in contact with a user's skin SK. For example, the user's skin SK may be the skin of the zygomatic bone, the skin of the mandible bone, or the skin of the cheek.

The inner cover 124 and 125 may include a horizontal part 124 and a vertical part 125. The horizontal part 124 may face or may be opposite to the outer cover 126. The vertical part 125 may be bent from the horizontal part 124. A space S may be formed between the horizontal part 124 of the inner cover 124 and 125 and the outer cover 126. The vertical part 125 may form a step 127. The outer cover 126 may be fixed to the step 127 of the vertical part 125. The outer cover 126 may be fixed to the vertical part 125 of the inner cover 124 and 125 by an adhesive member AD. For example, the adhesive member AD may be tape or glue.

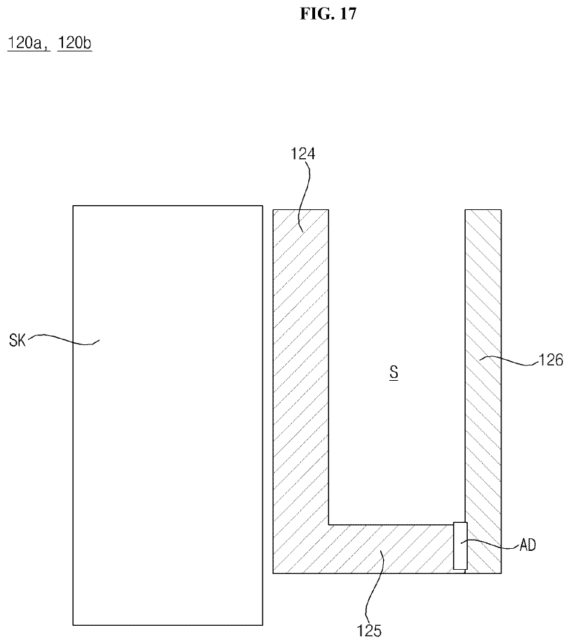

Referring to FIG. 17, the side frame 120a and 120b may include the inner cover 124 and 125 and the outer cover 126. The outer cover 126 may be coupled to the inner cover 124 and 125. The inner cover 124 and 125 may be in contact with body tissue SK forming the appearance of a user. For example, the inner cover 124 and 125 may be in contact with a user's skin SK. For example, the user's skin SK may be the skin of the zygomatic bone, the skin of the mandible bone, or the skin of the cheek.

The inner cover 124 and 125 may include a horizontal part 124 and a vertical part 125. The horizontal part 124 may face or may be opposite to the outer cover 126. The vertical part 125 may be bent from the horizontal part 124. A space S may be formed between the horizontal part 124 of the inner cover 124 and 125 and the outer cover 126. The outer cover 126 may be fixed to a distal end of the vertical part 125. The outer cover 126 may be fixed to the vertical part 125 of the inner cover 124 and 125 by an adhesive member AD. For example, the adhesive member AD may be tape or glue.

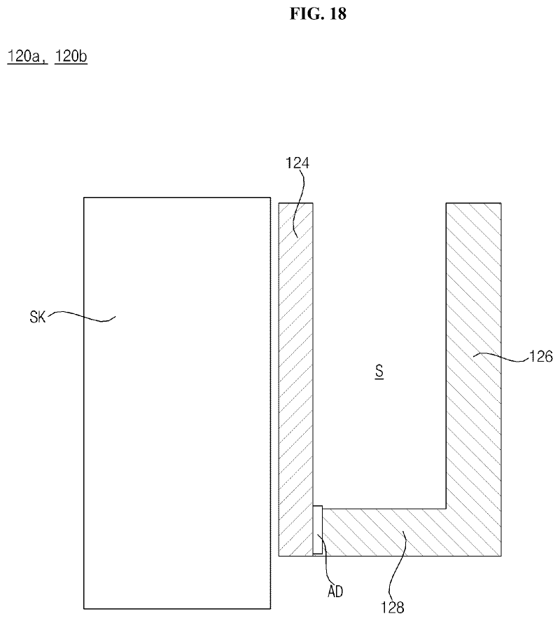

Referring to FIG. 18, the side frame 120a and 120b may include the inner cover 124 and the outer cover 126 and 128. The outer cover 126 and 128 may be coupled to the inner cover 124. The inner cover 124 may be in contact with body tissue SK forming the appearance of a user. For example, the inner cover 124 may be in contact with a user's skin SK. For example, the user's skin SK may be the skin of the zygomatic bone, the skin of the mandible bone, or the skin of the cheek.

The outer cover 126 and 128 may include a horizontal part 126 and a vertical part 128. The horizontal part 126 may face or may be opposite to the inner cover 124. The vertical part 128 may be bent from the horizontal part 126. A space S may be formed between the horizontal part 126 of the outer cover 126 and 128 and the inner cover 124. The inner cover 124 may be fixed to a distal end of the vertical part 128. The outer cover 126 and 128 may be fixed to the inner cover 124 by an adhesive member AD. For example, the adhesive member AD may be tape or glue.

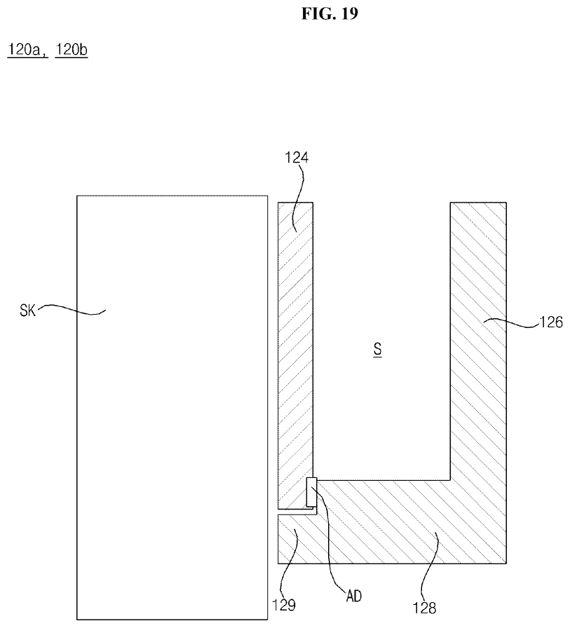

Referring to FIG. 19, the side frame 120a and 120b may include the inner cover 124 and the outer cover 126 and 128. The outer cover 126 and 128 may be coupled to the inner cover 124. The inner cover 124 may be in contact with body tissue SK forming the appearance of a user. For example, the inner cover 124 may be in contact with a user's skin SK. For example, the user's skin SK may be the skin of the zygomatic bone, the skin of the mandible bone, or the skin of the cheek.

The outer cover 126 and 128 may include a horizontal part 126 and a vertical part 128. The horizontal part 126 may face or may be opposite to the inner cover 124. The vertical part 128 may be bent from the horizontal part 126. A space S may be formed between the horizontal part 126 of the outer cover 126 and 128 and the inner cover 124. The vertical part 128 of the outer cover 126 and 128 may form a stepped portion 129. The inner cover 124 may be fixed to the stepped portion 129 of the vertical part 128 of the outer cover 126 and 128. The outer cover 126 and 128 may be fixed to the inner cover 124 by an adhesive member AD. For example, the adhesive member AD may be tape or glue.

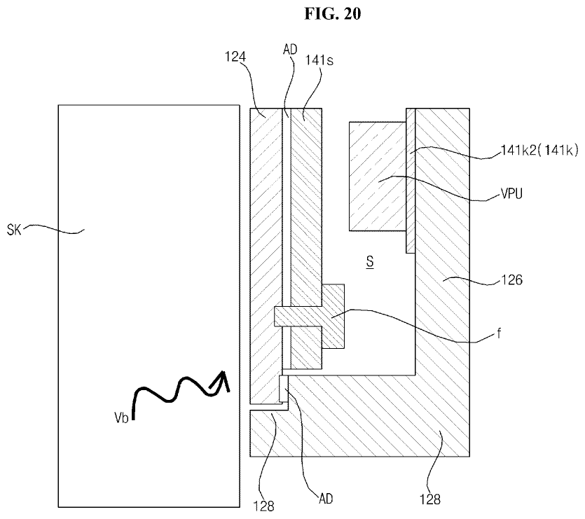

Referring to FIG. 20, the flat board 141s may be fixed to the inside of the inner cover 124. For example, the flat board 141s may be a PCB. The flat board 141s may be fixed to an inner surface of the inner cover 124 by an adhesive member AD. For example, the adhesive member AD may be tape or glue. The flat board 141s may be fixed to an inner surface of the inner cover 124 by a fastening member f. For example, the fastening member f may be a screw.

The input device VPU may be fixed to an inner surface of the horizontal part 126 of the outer cover 126 and 128. For example, the input device VPU may be a vibration sensor. The input board 141k may be fixed to an inner surface of the horizontal part 126 of the outer cover 126 and 128, and the input device VPU may be mounted on the head 141k2 of the input board 141k. For example, the input board 141k may be an FPCB. The input board 141k may extend from the flat board 141s. The input board 141k may be electrically connected to the flat board 141s. The input board 141k may be fixed to an inner surface of the horizontal part 126 of the outer cover 126 and 128 by an adhesive member AD. For example, the adhesive member AD may be tape or glue.

Accordingly, when a user touches their skin, the vibration Vb may be transferred to the input device VPU, and noise transferred to the input device VPU may be minimized.

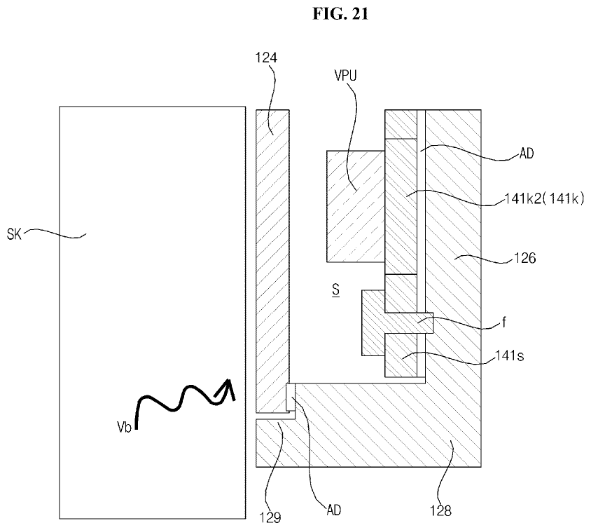

Referring to FIG. 21, the flat board 141s may be fixed to the inside of the horizontal part 126 of the outer cover 126 and 128. For example, the flat board 141s may be a PCB. The flat board 141s may be fixed to an inner surface of the horizontal part 126 of the outer cover 126 and 128 by an adhesive member AD. For example, the adhesive member AD may be tape or glue. The flat board 141s may be fixed to the inner surface of the horizontal part 126 of the outer cover 126 and 128 by a fastening member f. For example, the fastening member f may be a screw.

The input device VPU may be fixed to the inside of the horizontal part 126 of the outer cover 126 and 128. For example, the input device VPU may be a vibration sensor. The input board 141k may be fixed to an inner surface of the outer cover 126, and the input device VPU may be mounted on the head 141k2 of the input board 141k. For example, the input board 141k may be a PCB. The input board 141k may extend from the flat board 141s. The input board 141k may be electrically connected to the flat board 141s. The input board 141k may be fixed to the inner surface of the horizontal part 126 of the outer cover 126 and 128 by an adhesive member AD. For example, the adhesive member AD may be tape or glue.

Accordingly, when a user touches their skin, the vibration Vb may be transferred to the input device VPU, and noise transferred to the input device VPU may be minimized.

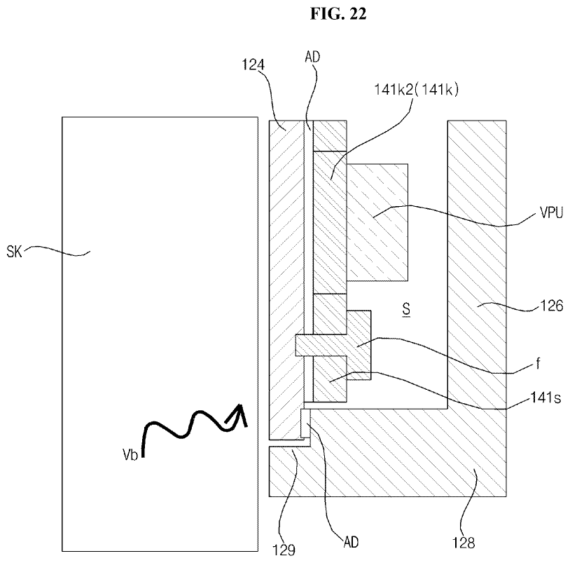

Referring to FIG. 22, the flat board 141s may be fixed to the inside of the inner cover 124. For example, the flat board 141s may be a PCB. The flat board 141s may be fixed to an inner surface of the inner cover 124 by an adhesive member AD. For example, the adhesive member AD may be tape or glue. The flat board 141s may be fixed to the inner surface of the inner cover 124 by a fastening member f. For example, the fastening member f may be a screw.

The input device VPU may be fixed to the inside of the inner cover 124. For example, the input device VPU may be a vibration sensor. The input board 141k may be fixed to an inner surface of the inner cover 124, and the input device VPU may be mounted on the head 141k2 of the input board 141k. For example, the input board 141k may be a PCB. The input board 141k may extend from the flat board 141s. The input board 141k may be electrically connected to the flat board 141s. The input board 141k may be fixed to the inner surface of the inner cover 124 by an adhesive member AD. For example, the adhesive member AD may be tape or glue.

Accordingly, when a user touches their skin, the vibration Vb may be transferred to the input device VPU, and noise transferred to the input device VPU may be minimized.

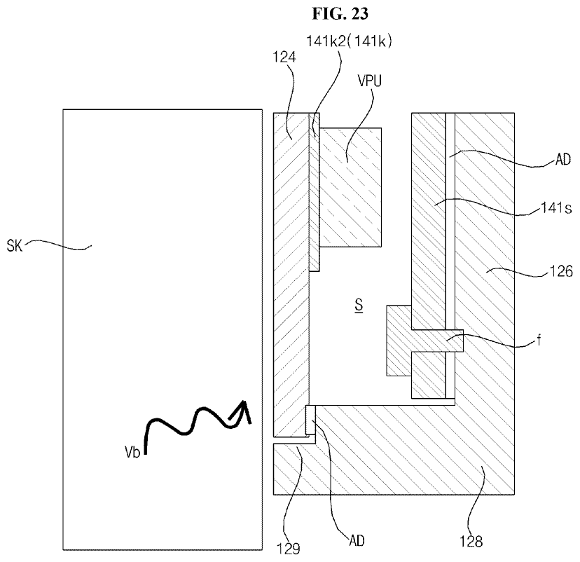

Referring to FIG. 23, the flat board 141s may be fixed to the inside of the horizontal part 126 of the outer cover 126 and 128. For example, the flat board 141s may be a PCB. The flat board 141s may be fixed to an inner surface of the horizontal part 126 of the outer cover 126 and 128 by an adhesive member AD. For example, the adhesive member AD may be tape or glue. The flat board 141s may be fixed to an inner surface of the horizontal part 126 of the outer cover 126 and 128 by a fastening member f. For example, the fastening member f may be a screw.

The input device VPU may be fixed to the inside of the inner cover 124. For example, the input device VPU may be a vibration sensor. The input board 141k may be fixed to an inner surface of the inner cover 124, and the input device VPU may be mounted on the head 141k2 of the input board 141k. For example, the input board 141k may be an FPCB. The input board 141k may extend from the flat board 141s. The input board 141k may be electrically connected to the flat board 141s. The input board 141k may be fixed to the inner surface of the inner cover 124 by an adhesive member (not shown). For example, the adhesive member may be tape or glue Accordingly, when a user touches their skin, the vibration Vb may be transferred to the input device VPU, and noise transferred to the input device VPU may be minimized.

Referring to FIGS. 1 to 23, an electronic device includes: a front frame to which a light-transmissive display unit is coupled; and a temple which is elongated and connected to the front frame, wherein the front frame includes: a PCB embedded in the front frame and extending from the front frame toward the temple; and a display panel embedded in the front frame at one side of the display unit and electrically connected to the PCB, wherein the temple includes: a flat board embedded in the temple and electrically connected to the PCB of the front frame; an input board embedded in the temple and electrically connected to the flat board; and a vibration sensor mounted on the input board, wherein the vibration sensor is fixed to an inside of the temple.

The flat board may be formed as a PCB, and the input board may be formed as a PCB or an FPCB extending from the flat board.

The temple may include an inner cover and an outer cover that are coupled to each other while facing each other, wherein the flat board may be fixed to an inside of the inner cover, and the input board may be fixed to an inside of the outer cover.

The vibration sensor may be disposed between the flat board and the input board and mounted on the input board, wherein the flat board may be fixed to the inner cover by an adhesive member, and the input board may be fixed to the outer cover by an adhesive member.

The flat board may be coupled to the inner cover by a fastening member.

The temple may include an inner cover and an outer cover that are coupled to each other while facing each other, wherein the flat board may be fixed to an inside of the outer cover, and the input board may be fixed to an inside of the inner cover.

The vibration sensor may be disposed between the flat board and the input board and mounted on the input board, wherein the flat board may be fixed to the outer cover by an adhesive member, and the input board may be fixed to the inner cover by an adhesive member.

The flat board may be coupled to the outer cover by a fastening member.

The temple may include an inner cover and an outer cover that are coupled to each other while facing each other, wherein the flat board may be fixed to an inside of the outer cover, and the input board may be fixed to the inside of the outer cover.

The flat board and the input board may be fixed to the inside of the outer cover by an adhesive member, and the flat board may be fixed to the inside of the outer cover by a fastening member.

The temple may include an inner cover and an outer cover that are coupled to each other while facing each other, wherein the flat board may be fixed to an inside of the inner cover, and the input board may be fixed to the inside of the inner cover.

The flat board and the input board may be fixed to the inside of the inner cover by an adhesive member, and the flat board may be fixed to the inside of the inner cover by a fastening member.

The front frame may include: a first rim defining a first opening; a second rim adjacent to the first rim and defining a second opening; and a bridge disposed between the first rim and the second rim and connecting the first rim and the second rim, wherein the display unit may include: a first display unit coupled to the first opening; and a second display unit coupled to the second opening, wherein the display panel may include: a first display panel disposed at one side of the first display unit, embedded in the first rim, and electrically connected to the PCB; and a second display panel disposed at one side of the second display unit, embedded in the second rim, and electrically connected to the PCB.

Information provided on the display panel may be displayed on a light transmission path of the display unit.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

The foregoing embodiments are merely examples and are not to be considered as limiting the present disclosure. The scope of the present disclosure should be determined by rational interpretation of the appended claims, and all modifications within the equivalents of the disclosure are intended to be included within the scope of the present disclosure.

1. An electronic device comprising:
a front frame to which a light-transmissive display unit is coupled; and
a temple which is elongated and connected to the front frame,
wherein the front frame comprises:
a PCB embedded in the front frame and extending from the front frame toward the temple; and
a display panel embedded in the front frame at one side of the display unit and electrically connected to the PCB,
wherein the temple comprises:
a flat board embedded in the temple and electrically connected to the PCB of the front frame;
an input board embedded in the temple and electrically connected to the flat board; and
a vibration sensor mounted on the input board,
wherein the vibration sensor is fixed to an inside of the temple.

2. The electronic device of claim 1, wherein the flat board is formed as a PCB, and the input board is formed as a PCB or an FPCB extending from the flat board.

3. The electronic device of claim 1, wherein the temple comprises an inner cover and an outer cover that are coupled to each other while facing each other,
wherein the flat board is fixed to an inside of the inner cover, and the input board is fixed to an inside of the outer cover.

4. The electronic device of claim 3, wherein the vibration sensor is disposed between the flat board and the input board and mounted on the input board,
wherein the flat board is fixed to the inner cover by an adhesive member, and the input board is fixed to the outer cover by an adhesive member.

5. The electronic device of claim 4, wherein the flat board is coupled to the inner cover by a fastening member.

6. The electronic device of claim 1, wherein the temple comprises an inner cover and an outer cover that are coupled to each other while facing each other,
wherein the flat board is fixed to an inside of the outer cover, and the input board is fixed to an inside of the inner cover.

7. The electronic device of claim 6, wherein the vibration sensor is disposed between the flat board and the input board and mounted on the input board,
wherein the flat board is fixed to the outer cover by an adhesive member, and the input board is fixed to the inner cover by an adhesive member.

8. The electronic device of claim 7, wherein the flat board is coupled to the outer cover by a fastening member.

9. The electronic device of claim 1, wherein the temple comprises an inner cover and an outer cover that are coupled to each other while facing each other,
wherein the flat board is fixed to an inside of the outer cover, and the input board is fixed to the inside of the outer cover.

10. The electronic device of claim 9, wherein the flat board and the input board are fixed to the inside of the outer cover by an adhesive member, and the flat board is fixed to the inside of the outer cover by a fastening member.

11. The electronic device of claim 1, wherein the temple comprises an inner cover and an outer cover that are coupled to each other while facing each other,
wherein the flat board is fixed to an inside of the inner cover, and the input board is fixed to the inside of the inner cover.

12. The electronic device of claim 11, wherein the flat board and the input board are fixed to the inside of the inner cover by an adhesive member, and the flat board is fixed to the inside of the inner cover by a fastening member.

13. The electronic device of claim 1, wherein the front frame comprises:
a first rim defining a first opening;
a second rim adjacent to the first rim and defining a second opening; and
a bridge disposed between the first rim and the second rim and connecting the first rim and the second rim,
wherein the display unit comprises:
a first display unit coupled to the first opening; and
a second display unit coupled to the second opening,
wherein the display panel comprises:
a first display panel disposed at one side of the first display unit, embedded in the first rim, and electrically connected to the PCB; and
a second display panel disposed at one side of the second display unit, embedded in the second rim, and electrically connected to the PCB.

14. The electronic device of claim 1, wherein information provided on the display panel is displayed on a light transmission path of the display unit.
